(19) United States
(12) Patent Application Publication
(10) Pub. No.: US 2026/0092359 A1
(43) Pub. Date: Apr. 2, 2026

(54) FILM FORMATION APPARATUS AND FILM FORMATION METHOD

(71) Applicant: SHIBAURA MECHATRONICS CORPORATION, Yokohama-shi (JP)

(72) Inventor: Hisashi NISHIGAKI, Yokohama-shi (JP)

(73) Assignee: SHIBAURA MECHATRONICS CORPORATION, Yokohama-shi (JP)

(21) Appl. No.: 19/331,557

(22) Filed: Sep. 17, 2025

(30) Foreign Application Priority Data
Aug. 13, 2025 (JP) 2025-134903
Sep. 30, 2024 (JP) 2024-171551

(51) Int. Cl. C23C 14/56; C23C 14/34; C23C 14/54

(52) U.S. Cl. CPC C23C 14/56; C23C 14/3407; C23C 14/54

(57) ABSTRACT

There is provided, according to one embodiment, a film formation apparatus including: a chamber; a lid body; a target; a film formation room; a conveyance body; a cylindrical part; an inward flange; an outward flange; a lift mechanism; and an evacuator, wherein the lift mechanism elevates the cylindrical part to bring the workpiece holder into contact with a lower edge of the lid body, causes the outward flange to come adjacent to and overlap with the inward flange, and causes the inside of the cylindrical part to communicate with the evacuator via the first through hole from the film formation room to perform vacuum evacuation of a processing space of the film formation room.

### CROSS REFERENCE TO RELATED APPLICATION

This application is based upon and claims the benefit of priority from the prior Japanese Patent Application No. 2024-171551, filed on September 30, 2024 and No. 2025-134903, filed on August 13, 2025, the entire contents of which are incorporated herein by reference.

### FIELD

Embodiments of the present invention relate to a film formation apparatus and a film formation method.

### BACKGROUND

As an apparatus that performs film formation on a surface of a workpiece such as a substrate, a film formation apparatus by sputtering is widely used. Sputtering is a technology of generating ions by making a process gas introduced into an evacuated chamber into plasma, causing the generated ions to collide with a surface of a target as a film formation material, and using the film formation material allowed to fly and adhere to the workpiece.

In recent years, sputter-type film formation apparatuses having a plurality of film formation rooms are being used. Some of these film formation apparatuses sequentially perform film formation processing in the individual film formation rooms through intermittent rotation of a rotation table on which workpieces are placed, the rotation table being arranged in a conveyance space common to the plurality of film formation rooms and intermittently rotating. In the case of such a film formation apparatus, there can occasionally occur contamination of process gases used in the film formation rooms via the conveyance space. This makes the film formation processing unstable.

Therefore, embodiments of the present invention provide a film formation apparatus and a film formation method enabling stable film formation processing.

### SUMMARY OF THE INVENTION

There is provided a film formation apparatus of an embodiment, including: a chamber configured such that an inside of the chamber is able to be evacuated to a vacuum; a lid body provided to face an interior of the chamber via an opening of an upper part of the chamber; a target provided on the lid body and formed to include a film formation material that is to be deposited on a workpiece as a processed object by sputtering; a film formation room in which a film is formed on the workpiece arranged on a workpiece holder through sputtering of the target with plasma, the film formation room being formed in the chamber by the lid body and the workpiece holder that includes a first through hole; a conveyance body configured to rotate intermittently and to position the workpiece holder at a position corresponding to the lid body, the workpiece holder being placed on the conveyance body; a cylindrical part configured to move the workpiece holder to a position in contact with the lid body from the conveyance body; an inward flange formed at a lower end of the cylindrical part and extending in an inward direction from the lower end; an outward flange configured to come adjacent to and overlap with the inward flange while the cylindrical part moves and to obstruct entry of evacuated gas into the chamber, the outward flange being provided inside the cylindrical part and extending in an outward direction in the cylindrical part; a lift mechanism configured to elevate and lower the cylindrical part such that the cylindrical part comes into contact with and separates from the workpiece holder; and an evacuator configured to perform vacuum evacuation, the evacuator being provided at an opening in a bottom part of the chamber to face the film formation room, wherein the lift mechanism elevates the cylindrical part to bring the workpiece holder into contact with a lower edge of the lid body, causes the outward flange to come adjacent to and overlap with the inward flange, and causes the inside of the cylindrical part to communicate with the evacuator to form a first evacuation line that performs vacuum evacuation of a processing space of the film formation room, via the first through hole from the film formation room.

### BRIEF DESCRIPTION OF THE DRAWINGS

FIG. 1 is a schematic configuration diagram of a film formation apparatus in an embodiment;

FIG. 2 is a cross sectional view taken along line A-A in FIG. 1 showing a configuration of a film former in the present embodiment;

FIG. 3 is a block diagram of a controller in the present embodiment;

FIG. 4 is a diagram for explaining a flow of plasma processing in the present embodiment;

FIG. 5 is a diagram for explaining the flow of plasma processing in the present embodiment;

FIG. 6 is a diagram for explaining the flow of plasma processing in the present embodiment;

FIG. 7 is a diagram for explaining the flow of plasma processing in the present embodiment;

FIG. 8 is a diagram for explaining the flow of plasma processing in the present embodiment;

FIG. 9 is a diagram for explaining the flow of plasma processing in the present embodiment;

FIG. 10 is a diagram for explaining the flow of plasma processing in the present embodiment;

FIG. 11 is a flowchart of plasma processing in the present embodiment;

FIG. 12 is a cross sectional view in forming an exclusive evacuation line for a film former in a first modification of the present embodiment;

FIG. 13 is a cross sectional view in forming an evacuation line for the entirety of the film former in the first modification of the present embodiment;

FIG. 14 is a cross sectional view in forming an exclusive evacuation line for a film former in a second modification of the present embodiment;

FIG. 15 is a cross sectional view in forming an evacuation line for the entirety of the film former in the second modification of the present embodiment;

FIG. 16 is a cross sectional view in forming an exclusive evacuation line for a film former in a third modification of the present embodiment; and

FIG. 17 is a cross sectional view in forming an evacuation line for the entirety of the film former in the third modification of the present embodiment.

### DETAILED DESCRIPTION OF THE EMBODIMENTS

Hereafter, embodiments of the present disclosure will be described with reference to the drawings. The embodiments do not limit the present invention. The drawings are schematical or conceptual, and proportions between individual portions are not necessarily equal to real ones. There may be cases where, in one or some of the drawings, lines to be cross sectionally viewed are omitted. In the specification and the drawings, similar elements to those described with the drawings that have been already described are given the same signs, and their detailed description is omitted where appropriate.

Moreover, in the present disclosure, the terms, "being not less than" and "being not more than", can be properly replaced by "exceeding" and "being less than", respectively. Moreover, the terms, "exceeding" and "being less than", can be properly replaced by "being not less than" and "being not more than", respectively.

Moreover, an X-axis, a Y-axis, and a Z-axis described below indicate the axes perpendicular to one another, a direction along the X-axis is an X-direction, a direction along the Y-axis is a Y-direction, and a direction along the Z-axis is a Z-direction. Note that the direction along each axis does not necessarily indicate the parallel direction thereto. The X-direction and the Y-direction correspond to traverse directions (horizontal directions) that intersect each other and are perpendicular to the direction of gravity, and the Z-direction corresponds to the longitudinal direction (vertical direction) that intersects the X-direction and the Y-direction, that is, the direction of gravity and should be regarded as not necessarily being parallel to the direction of gravity. Moreover, the +Z-direction corresponds to an upward direction, and the -Z-direction corresponds to a downward direction. The X-direction is an example of a first direction, the Y-direction is an example of a second direction, and the Z-direction is an example of a third direction.

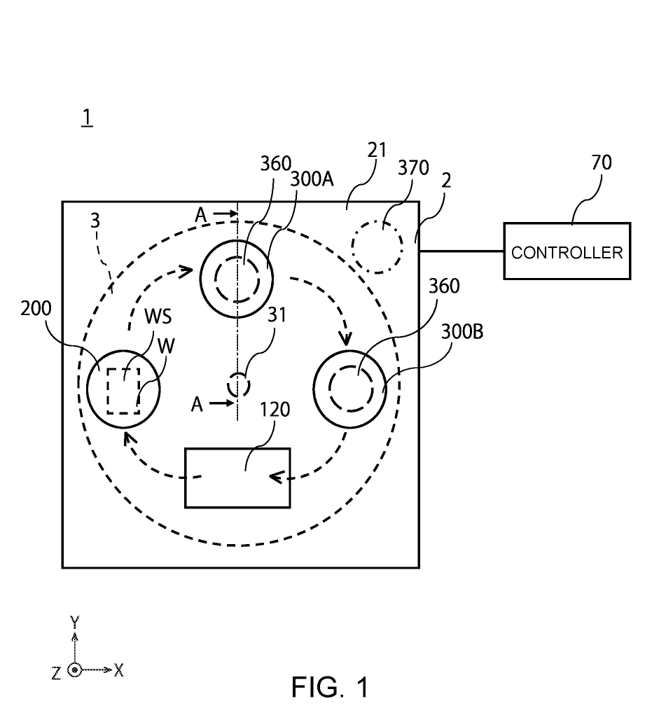

FIG. 1 is a schematic configuration diagram of a film formation apparatus 1 in the present embodiment.

An example of the film formation apparatus 1 of the present embodiment is a plasma processing apparatus that performs film formation using plasma on film formation target surfaces WS of individual workpieces W. In the present embodiment, the film formation apparatus 1 includes a chamber 2, a rotation table 3, a load lock 120, a preprocessing device 200, film formers 300 (300A and 300B), and a controller 70. The film formation apparatus 1 of the present embodiment has, in the chamber 2 that can be evacuated to a vacuum, the rotation table 3 that holds the workpieces W and intermittently rotates by every 90°. The film formation apparatus 1 performs various processes on the workpieces W at (four) stop positions where the rotation table 3 stops by every 90°. The processes at the individual positions are performed simultaneously or not simultaneously. Accordingly, the processing devices may be evenly arranged on a circle concentric with the rotation table 3 around the center of the rotation table 3. Each of the processing devices may include one processing device or may include a plurality of processing devices. The number of the stop positions is not limited to that in the example of FIG. 1, and various stop positions may be provided.

The film formation apparatus 1 shown in FIG. 1 is an example including one load lock 120, one preprocessing device 200, and two film formers 300. At the load lock 120, a workpiece W before processing is carried into the chamber 2, and the workpiece W carried into is intermittently conveyed clockwise in the figure by the rotation table 3. The workpiece W conveyed in the chamber 2 first undergoes preprocessing before film formation processing at the preprocessing device 200, and then undergoes the same or different film formation processing (sputtering) at the film formers 300A and 300B. The workpiece W after the processes is taken out outside the chamber 2 at the load lock 120. Operation and processing of each part are controlled by the controller 70.

While the film formation apparatus 1 in the present embodiment can process the plurality of workpieces W with these simultaneously conveyed, the following description focuses on one workpiece W.

At the individual stop positions, the load lock 120, the preprocessing device 200, the film former 300A, and the film former 300B are placed. In the state where the vacuum inside the chamber 2 is kept, the load lock 120 carries the workpiece W that is unprocessed from the outside into the inside of the chamber 2, and takes out the processed workpiece W to the outside of the chamber 2.

The film formation apparatus 1 according to the present embodiment is a film formation apparatus in what is called a multi-chamber configuration having the plurality of film formers 300A to 300B. While in the present embodiment, there is illustrated a configuration having two film formers 300A to 300B as shown in FIG. 1, one film former or a plurality of film formers may be provided.

In the present embodiment, a flat plate-shaped ceramic substrate is used as an example of the workpiece W to be processed. Note that the type, the shape, and the material of the workpiece W are not limited to specific ones. For example, the shape of the substrate may be shapes of a substrate partially or entirely having recesses or/and projections and a substrate curved concave or/and convex, being not limited to the flat plate shape. Moreover, that of the substrate is not limited to a rectangle, and may be a polygon or a circle. Moreover, the substrate only has to be a solid material, and may include a conductive material such as metal and carbon, an insulator such as glass and rubber, and/or a semiconductor such as silicon. Moreover, configurations and applications of formed films are not limited to specific ones. The formed films may be used for various applications such as decoration, protection, optical applications such as antireflection, and information recording. Moreover, the number of workpieces W that simultaneously undergo plasma processing at each stop position is not limited to a specific number.

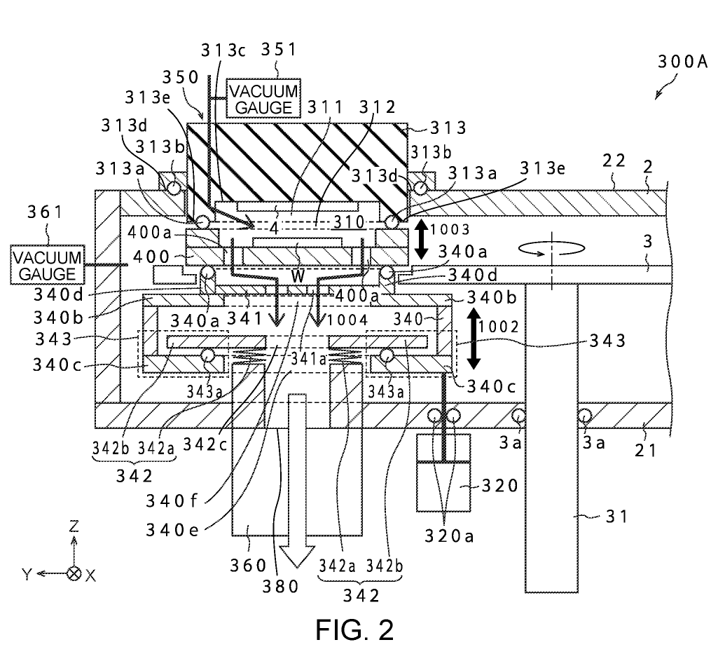

As shown in FIGS. 1 and 2, the chamber 2 is a container the inside of which can be evacuated to a vacuum. The chamber 2 of the present embodiment has a box shape as a rectangular solid shape, and has a bottom plate 21 on the side of being installed and a lid plate 22 on the opposite side. While, in the present embodiment, it has a rectangular solid shape, the chamber 2 may have any shape. For example, the shape of the chamber may be a shape along the rotation table 3, that is, a cylindrical shape. On the chamber 2, evacuators 360 are provided respectively beneath the film formers 300A and 300B. Each evacuator 360 of the present embodiment has piping connected to an opening 380 formed in the bottom plate 21 of the chamber 2. The evacuator 360 includes a not-shown pneumatic circuit, and hence, can perform vacuum evacuation in the chamber 2 by evacuation processing. Moreover, there may be included, in addition to these evacuators 360, an evacuator 370 that evacuates the entire chamber 2.

These evacuators 360 work as exclusive evacuators 360 respectively for the film formers 300A and 300B in film formation, and can evacuate processing spaces of respective film formation rooms. Except in film formation, they perform evacuation processing of the entire chamber 2 to evacuate the chamber 2.

The rotation table 3 is a conveyance apparatus that rotates in a θ-direction which is a rotational direction with the Z-direction being as a rotary axis and conveys the workpieces W in the chamber 2. The rotation table 3 has a circular plate shape, and intermittently rotates (performs intermittent conveyance) around a shaft 31 by a not-shown drive source. On the rotation table 3, openings having grooves in which workpiece holders 400 are placed are formed at positions evenly arranged on the circumference. Four openings are provided at 90° intervals correspondingly to the load lock 120, the preprocessing device 200, the film former 300A, and the film former 300B. As shown in FIG. 2, a sealing material 3a such as an O-ring provides sealing between the shaft 31 and the bottom plate 21. The rotation table 3 is an example of a conveyance body.

The load lock 120 is an apparatus that, in the state where the vacuum of the chamber 2 is kept, with a not-shown conveyance device, carries the workpiece holder 400 on which the unprocessed workpiece W is placed from the outside into the chamber 2 and takes out the workpiece holder 400 on which the processed workpiece W is placed to the outside of the chamber 2.

The preprocessing device 200 performs bombardment processing on the workpiece W. In the bombardment processing, plasma is generated in the processing room, and modification processing on a surface of the workpiece W is performed with the plasma. The bombardment processing can remove moisture, contaminants (organic matters), foreign objects, and the like on the surface of the workpiece W on which a film to be formed, and can enhance adhesion of a film formed in the next film formation step.

The film formers 300A and 300B are apparatuses that perform film formation on the workpiece W as a processed object. In each of the film formation rooms in the film formers 300A and 300B, a voltage is applied to a process gas G in the processing space to generate plasma, ions in the plasma strike a target that is composed of sources of the film material to cause sputter particles to fly out, and the sputter particles are deposited on the workpiece W to form the film. The film former 300A performs film formation processing on the workpiece W that, after undergoing the bombardment processing by the preprocessing device 200, is intermittently conveyed from the rotation table 3. In the present embodiment, the film former 300B performs film formation processing on the workpiece W using a different target by the similar method to that for the film former 300A. Note that the film former 300A or the film former 300B may perform reactive sputtering processing of applying a voltage to the process gas G in the processing space to generate plasma and causing the film to chemically react with ions in the plasma to generate a compound film. In the film former 300B, film formation processing (sputtering) the same as or different from that in the film former 300A is performed.

The process gas G is gas that is made into plasma by application of a voltage to a not-shown antenna, and ions generated from which are caused to collide with the target to deposit a film formation material of the target on a surface of the workpiece W. For example, inert gas such as argon gas can be used as the process gas G.

In the present embodiment, as to the film formers 300A and 300B, for example, the film formers are continuously arranged in the conveyance direction (the broken line arrows shown in FIG. 1). The number of the film formers may be determined based on the number of types of film formation materials deposited on the workpiece. Moreover, in the plurality of film formers, targets of different film formation materials may be arranged, or targets of the same type of film formation materials may be arranged.

The controller 70 controls the parts of the film formation apparatus 1. The controller 70 is programmed to perform the contents of control of the plasma processing, which are executed by a processing apparatus such as a CPU (central processing unit). For example, the controller 70 performs evacuation of the chamber 2, control of the preprocessing device 200 and the film formers 300A and 300B, and the like.

FIG. 2 is a cross sectional view taken along line A-A showing a configuration of the film former 300A in the present embodiment.

FIG. 2 shows a state where, after completion of the preprocessing by the preprocessing device 200, the control by the controller 70 performs intermittent conveyance by the rotation table 3 and positions the workpiece holder 400 at an opening 311 of the film former 300A.

The film former 300A, 300B in the present embodiment has a film formation room 310, a cylinder 320, a cylindrical part 340, an inflow obstructor 341, a bellows mechanism 342, a process gas introducer 350, and the evacuator 360.

The film formation room 310 is a processing space in which a film is formed on the workpiece W through sputtering of a target 4 with ions generated from plasma which is made with the process gas G introduced by the process gas introducer 350. As shown in FIG. 2, the film formation room 310 is constituted of, in addition to the opening 311 and a lid body 313, the workpiece holder 400 intermittently conveyed by the rotation table 3. The opening 311 is a through hole provided in the lid plate 22 of the chamber 2. The lid body 313 is a casing that is provided in the opening 311 and seals an upper part of the workpiece holder 400. Moreover, the lid body 313 is provided such that a lid rear 313c faces the bottom plate 21 of the chamber 2. The lid body 313 is supported by the lid plate 22. A sealing material 313b is provided on the lid body 313 side, and this sealing material 313b and the lid plate 22 are in airtight contact with each other, which thereby provides sealing between the lid plate 22 and the lid body 313. The sealing material 313b such as an O-ring provides sealing between the lid plate 22 and the lid body 313. Moreover, the sealing material 313b is provided on a lower edge 313d of the lid body 313, and a sealing material 313a similarly such as an O-ring provides sealing between the workpiece holder 400 and a lower edge 313e of the lid body 313. Moreover, the target 4 is provided on the lid rear 313c of the lid body 313. The target 4 is held so as to face the workpiece W with a not-shown backing plate.

The target 4 is a member formed of the film formation material which is to be deposited on the workpiece W to be a film. For the film formation material, for example, silicon, niobium, tantalum, titanium, aluminum, and the like are used. Note that various materials are applicable as long as they are materials that can be deposited by sputtering. When a plurality of targets 4 are included, they may be common materials or may be different types of materials. Moreover, the target 4 has, for example, a cylindrical shape. Note that it may have another solid shape such as a long cylindrical shape and a prismatic shape. When a high voltage is applied to each target 4, the process gas G fed between the target 4 and the workpiece W is made into plasma, and the film formation material can be deposited on the workpiece W. While in the present embodiment, an example of a power supplier supplying electric power is a DC power supply, it may be an RF power supply which applies a high frequency voltage. In the DC power supply scheme, a not-shown ground is provided on the lid body 313 side.

The cylindrical part 340 moves, with operation of the cylinder 320, in a direction of coming into contact with and separating from the workpiece holder 400, and forms an evacuation line in which a processing space 312 in the film formation room 310 and the cylindrical part 340 communicate with each other. The processing space 312 is a space formed between the workpiece holder 400 and the lid body 313 when the workpiece holder 400 comes into contact with the lid body 313 via the sealing material 313a. A surface that the cylindrical part 340 and a lower surface of the workpiece holder 400 are in contact with is sealed with a sealing material 340a such as an O-ring. With the direction of motion of the cylindrical part 340 being as the axial direction, an inward flange 340b and an inward flange 340c that extend inward in the radial direction from end parts in the axial direction of the cylindrical part 340, that is, inward from an upper end and a lower end of the cylindrical part 340, respectively, are provided at the upper end and the lower end, respectively, in the cylindrical part 340. The direction inward in the radial direction of the cylindrical part 340 is also called an inward direction. The inward flanges 340b and 340c have, at their centers, openings 340f and 340e, respectively. Moreover, the inward flange 340b has a supporter 340d protruding in the direction of coming into contact with the workpiece holder 400. This supporter 340d is provided into a ring shape on an upper surface of the inward flange 340b so as to face the workpiece holder 400. Moreover, the sealing material 340a is provided at an upper end of the supporter 340d. The supporter 340d comes into contact with the workpiece holder 400 via the sealing material 340a.

The cylinder 320 is a member that can cause the cylindrical part 340 to come into contact with and separate from the workpiece holder 400. With motion of the cylindrical part 340, the workpiece holder 400 comes into contact with and separates from the lower edge 313e of the lid body 313. A sealing material 320a such as an O-ring provides sealing between the cylinder 320 and the bottom plate 21. The cylinder 320 is an example of a motion mechanism.

The process gas introducer 350 has piping that introduces the process gas G. The process gas introducer 350 includes a not-shown gas feed circuit, and introduces, based on control by the controller 70, the process gas G from a feed source into the processing space 312 in the film formation room 310. Moreover, the process gas introducer 350 includes a vacuum gauge 351 that measures a pressure in the film formation room 310. The vacuum gauge 351 is an example of a first vacuum gauge.

The inflow obstructor 341 is a circular plate-shaped member that is arranged on the cylindrical part 340 and obstructs inflow of plasma into the cylindrical part 340. In the present embodiment, the inflow obstructor 341 is arranged on the inner side of the supporter 340d on the inward flange 340b, and has a plurality of through holes 341a. For example, four through holes 341a are provided along the circumference of the inflow obstructor 341. Note that the number of the through holes 341a is not limited to this and may take any of various numbers.

The workpiece holder 400 is a dish-like member that holds the workpiece W. The workpiece holder 400 in the present embodiment has a plurality of through holes 400a. For example, the through holes 400a are provided outside a portion of the workpiece holder 400 on which the workpiece W is placed. For example, four through holes 400a are provided along the circumference thereof.

The through holes 341a and the through holes 400a are arranged so as not to overlap with each other in the Z-direction. The through holes 341a and the through holes 400a are arranged in the inflow obstructor 341 and the workpiece holder 400, respectively, so as to be shifted in the circumferential direction and/or in the radial direction. Moreover, the number of the through holes 341a and the number of the through holes 400a may be different as long as those are arranged so as not to overlap with each other in the Z-direction. In the present embodiment, as shown in FIG. 2, those are arranged so as to be shifted in the radial direction.

Moreover, the supporter 340d is configured to form a gap between the inflow obstructor 341 and the workpiece holder 400 when the workpiece holder 400 and the cylindrical part 340 comes into contact with each other.

In sputtering, the cylindrical part 340 elevates the workpiece holder 400, and an edge part of the workpiece holder 400 comes into contact with the lid body 313. In this stage, the cylindrical part 340 and the workpiece holder 400 comes into contact with each other. Moreover, the inward flange 340c comes into contact with an outward flange 342b mentioned later. Moreover, in sputtering, the film formation room 310 becomes full of the process gas G. In this stage, a film results in being deposited also on the through holes 400a and/or 341a. When the through holes 400a and the through holes 341a are arranged on identical lines, there is a possibility that sputter particles flow into the through holes 400a and the through holes 341a to be deposited as film(s) and some of the through holes are closed. When any of the through holes are closed, the workpiece holder 400 is to be pulled to the evacuator 360 side due to a suction force of the evacuator 360. There eventually occurs a situation of damage such as cracks in the workpiece holder 400 and/or the workpiece W. Moreover, when any of the through holes 341a of the inflow obstructor 341 are closed, likewise, there can occur a situation that the inflow obstructor 341 is pulled to the evacuator 360 side due to the suction force of the evacuator 360 and the inflow obstructor 341 cracks. Therefore, in the film former 300A of the present embodiment, a space is provided between the workpiece holder 400 and the inflow obstructor 341. Furthermore, the through holes 400a and the through holes 341a are arranged so as to not be on the same lines.

Moreover, sizes of diameters of the through holes 341a and the through holes 400a may be any sizes as long as the holes are not closed with sputter particles. Each of the through holes 400a is an example of a first through hole, and each of the through holes 341a is an example of a second through hole.

The evacuator 360 is arranged in the opening 380 provided in a bottom part of the chamber 2. Moreover, its position is a position right below the film formation room 310. The evacuator 360 includes, for example, a turbopump and can perform vacuum evacuation in the film formation room 310 by evacuation processing. Moreover, a vacuum gauge 361 is included in the chamber 2 in order to measure change in pressure due to the evacuation. The vacuum gauge 361 is an example of a second vacuum gauge.

The bellows mechanism 342 includes bellows 342a and the outward flange 342b. The outward flange 342b is smaller than an inner diameter of the cylindrical part 340, and inside the cylindrical part 340, extends outward in the radial direction of the cylindrical part 340. The direction outward in the radial direction of the cylindrical part 340 is also called an outward direction. It extends in the outward direction from the opening 340e in the bottom part of the chamber 2 where the evacuator 360 is arranged. An opening 342c is included at the center of the outward flange 342b. Moreover, the outward flange 342b is supported by the bellows 342a. The bellows mechanism 342 is provided in the opening 380 of the bottom part of the chamber 2, and forms an evacuation path connecting the cylindrical part 340 and the evacuator 360 by allowing the bellows 342a extending toward the inside of the cylindrical part 340 to expand and contract. The bellows mechanism 342 is connected to an upper part of the evacuator 360, and has a structure in which, when the cylindrical part 340 moves in the +Z-direction, the outward flange 342b comes adjacent to and overlaps with the inward flange 340c provided on an inner surface of the cylindrical part 340. As to the inward flange 340c, a sealing material 343a such as an O-ring is provided on a surface that overlaps with the outward flange 342b (inner surface of the cylindrical part 340 in the present embodiment). A structure of preventing suction and/or evacuation from a gap between the inward flange 340c and the outward flange 342b using the inward flange 340c of the cylindrical part 340 and the outward flange 342b of the bellows mechanism 342 is hereafter also called a trap structure 343 like a structure indicated by broken lines in the figure.

When the cylindrical part 340 moves in the +Z-direction, the outward flange 342b is elevated by the inward flange 340c, and the bellows 342a extends in the +Z-direction. The bellows 342a enables the cylindrical part 340 to move upward and downward while forming the evacuation line. When the cylindrical part 340 is elevated by the cylinder 320, the outward flange 342b and the inward flange 340c come into contact with each other via the sealing material 343a, and a gap between the outward flange 342b and the inward flange 340c arising due to an allowance is restrained. In other words, providing the sealing material 343a restrains evacuated gas from leaking through the gap between the outward flange 342b and the inward flange 340c. Moreover, when the cylindrical part 340 is elevated, the cylindrical part 340 comes into contact with the workpiece holder 400 via the sealing material 340a, and the workpiece holder 400 comes into contact with the lid body 313 via the sealing material 313a. In this stage, the processing space 312 in the film formation room 310 comes to communicate with the through holes 400a of the workpiece holder 400, the through holes 341a of the inflow obstructor 341, and the inside (from the opening 340f to the opening 340e) of the cylindrical part 340, which forms an evacuation line for this space. This evacuation line is connected to the evacuator 360, and allows vacuum evacuation of the processing space 312 in the film formation room 310 to be performed. This exclusive evacuation line is also called a first evacuation line.

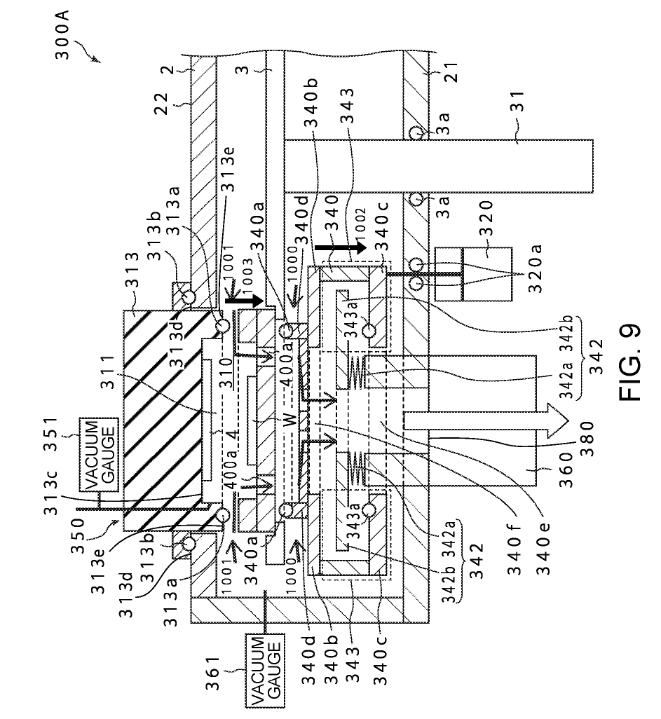

When the cylindrical part 340 is lowered by the cylinder 320 to be separated from the workpiece holder 400, a gap is formed between the cylindrical part 340 and the workpiece holder 400, which forms an evacuation line for the entire chamber 2 passing from this gap through the inside (from the opening 340f to the opening 340e) of the cylindrical part 340 via the inflow obstructor 341 (see FIG. 9). This evacuation line is connected to the evacuator 360, and allows vacuum evacuation to be performed. This evacuation line for the entire chamber 2 is also called a second evacuation line. Moreover, when the cylindrical part 340 is lowered by the cylinder 320, before the gap is formed between the cylindrical part 340 and the workpiece holder 400, a gap also formed between the lid body 313 and the workpiece holder 400. This also forms an evacuation line for the entire chamber passing from this gap through the through holes 400a, the through holes 341a, and the inside of the cylindrical part 340. This evacuation line for the entire chamber 2 is also called a third evacuation line.

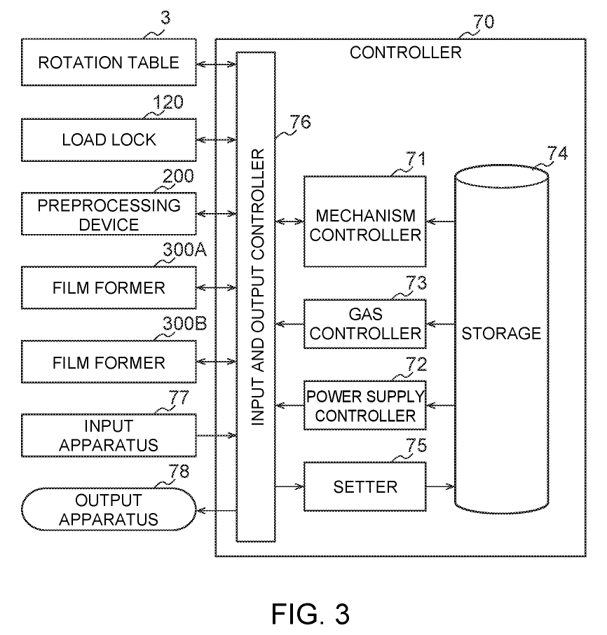

FIG. 3 is a block diagram of the controller 70 in the present embodiment.

For example, the controller 70 can be implemented by installing a program for the controller 70 into a PC (programmable controller). By the CPU in the controller 70 executing the program for the controller 70, functions of a mechanism controller 71, a power supply controller 72, a gas controller 73, a storage 74, a setter 75, and an input and output controller 76 are implemented. For example, the storage 74 is constructed on a storage device of an HDD (hard disc drive).

The mechanism controller 71 controls drive sources for the rotation table 3, the load lock 120, the preprocessing device 200, and the film formers 300A and 300B. The power supply controller 72 controls a not-shown power supply. For example, the power supply controller 72 controls a voltage applied to the target 4. By enhancing the value of the applied voltage, a thickness of the film formed on the workpiece W can be made large, and by lowering the value of the applied voltage, the thickness of the film can be made small.

The gas controller 73 controls an amount of introduction of the process gas G by controlling a feed source and a valve for the gas. The storage 74 stores information used for the control of the present embodiment. The setter 75 sets information, for example, input by an operator through an input apparatus 77 into the storage 74. For example, the setter 75 sets the applied voltage to the target 4.

The input and output controller 76 is an interface that controls conversion, input, and output of signals with/from/to the individual parts as control targets. Furthermore, the input apparatus 77 and an output apparatus 78 are connected to the controller 70. The input apparatus 77 is an input device including switches, a touch panel, a keyboard, a mouse, and the like for an operator to manipulate the film formation apparatus 1 via the controller 70.

The output apparatus 78 is an output device including a display, lamps, meters, and the like that enable the operator to visually recognize information for examining states of the apparatuses. For example, the output apparatus 78 can display an input screen for the information from the input apparatus 77.

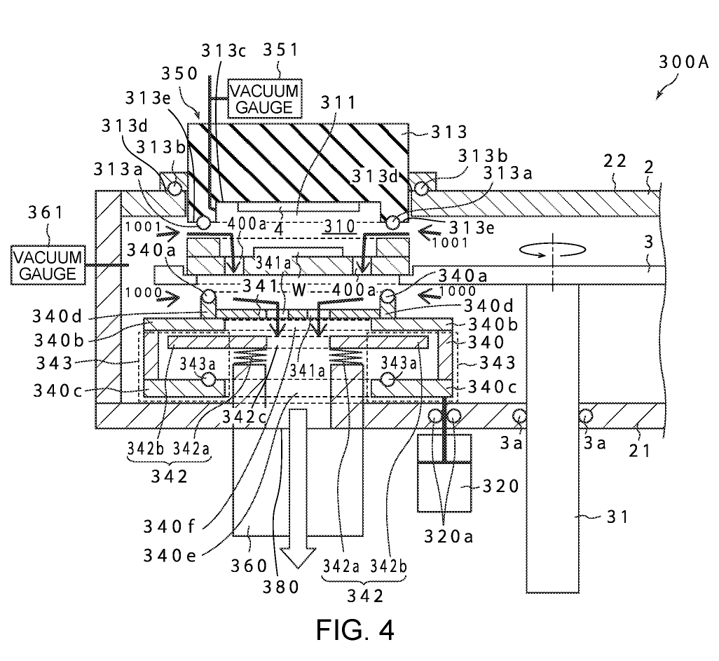

A flow of plasma processing in the present embodiment is described using FIGS. 4 to 11. Moreover, since the similar processing is performed for each of the film formers 300A and the 300B, the flow for the film former 300A is intensively described.

As shown in FIG. 4, in the film formation apparatus 1 in the present embodiment, by intermittent conveyance by the rotation table 3, the workpiece W placed on the workpiece holder 400 is positioned at a position corresponding to the opening 311 of the film former 300A. Note that the description is made as this workpiece W having undergone the preprocessing by being conveyed to the preprocessing device 200 from the load lock 120. Moreover, by the time before the workpiece W is carried into the chamber 2 by the load lock 120, the inside of the chamber 2 has undergone vacuum evacuation by the evacuator 370 so as to have a predetermined pressure.

After undergoing surface processing by the preprocessing device 200, the workpiece W is conveyed to a position facing the opening 311 of the film former 300A by intermittent conveyance by the rotation table 3 (step S1).

In FIG. 4, the cylinder 320 lowers the cylindrical part 340. In this stage, a gap arises between the cylindrical part 340 and the workpiece holder 400. The evacuator 360 operates, and as indicated by directions of arrows 1000, a line passing from the chamber 2 through the inflow obstructor 341 and the evacuator 360 via this gap is formed as an evacuation line for the entire chamber 2. In this state, vacuum evacuation is performed such that the evacuator 360 keeps a predetermined pressure in the chamber 2 (step S2). Note that vacuum evacuation in the chamber 2 is performed all the time, as indicated by directions of arrows 1001, with an evacuation line passing from a gap between the lid body 313 and the workpiece holder 400 through the through holes 400a, the through holes 341a, and the inside of the cylindrical part 340.

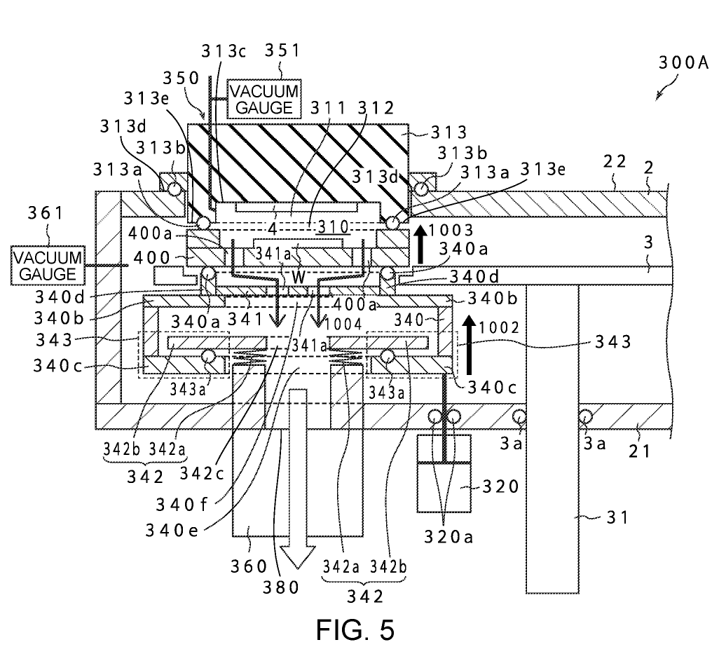

Next, as shown in FIG. 5, the cylinder 320 elevates the cylindrical part 340. As indicated by an arrow 1002 and an arrow 1003, the elevation of the cylindrical part 340 brings the sealing material 340a into contact with the lower side of the workpiece holder 400, the workpiece holder 400 in the state of the contact therewith is elevated to be separated from the rotation table 3, and the outer edge of the workpiece holder 400 comes into contact with the sealing material 313a at the lower edge 313e of the lid body 313. At the time of this state, the cylinder 320 stops elevating the cylindrical part 340. Moreover, the outward flange 342b is pressed onto the inward flange 340c such that the sealing is not relieved due to being pressed with the chamber 2 pressure.

As above, the sealing material 313a provides sealing between the lid body 313 and the workpiece holder 400, the sealing material 340a provides sealing between the workpiece holder 400 and the cylindrical part 340, the sealing material 343a provides sealing between the cylindrical part 340 and the bellows mechanism 342, and thereby, the inside of the cylindrical part 340 is sealed from the inside of the chamber 2. Thereby, the inside of the cylindrical part 340 is prevented from communicating with the inside of the chamber 2, which forms an exclusive evacuation line for the film formation room 310 which causes the film formation room 310 to communicate only with the evacuator 360. In other words, this evacuation line is a line passing from the inside of the film formation room 310 through the cylindrical part 340 via the through holes 400a and the through holes 341a (indicated by arrows 1004 passing through the through holes 400a and 341a in FIG. 5). Moreover, in this stage, vacuum evacuation is performed such that the film formation room 310 has a predetermined pressure lower than the pressure in the chamber 2.

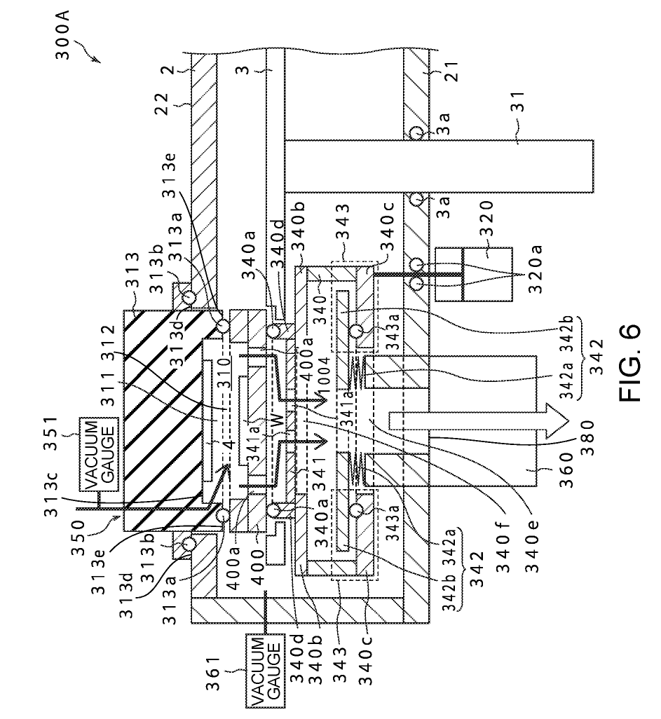

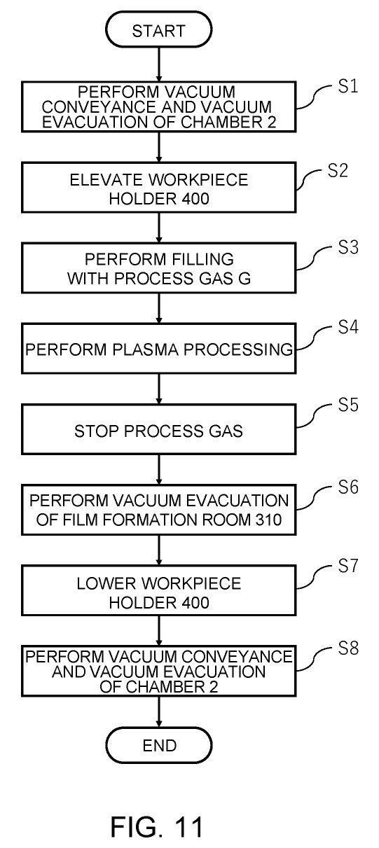

After the pressure in the film formation room 310 becomes the predetermined pressure lower than the pressure in the chamber 2, the process gas G is fed (see FIG. 6 and step S3 in FIG. 11).

In this stage, the process gas introducer 350 feeds the process gas G from a gas feed source to the film formation room 310. Even after the inside of the film formation room 310 is filled with the process gas G, feed of the process gas G and evacuation by the evacuator 360 are continued such that the predetermined pressure is kept in the film formation room 310. Note that the predetermined pressure in the film formation room 310 is a pressure at which plasma processing can be properly performed, and is set to be higher than the pressure in the chamber 2.

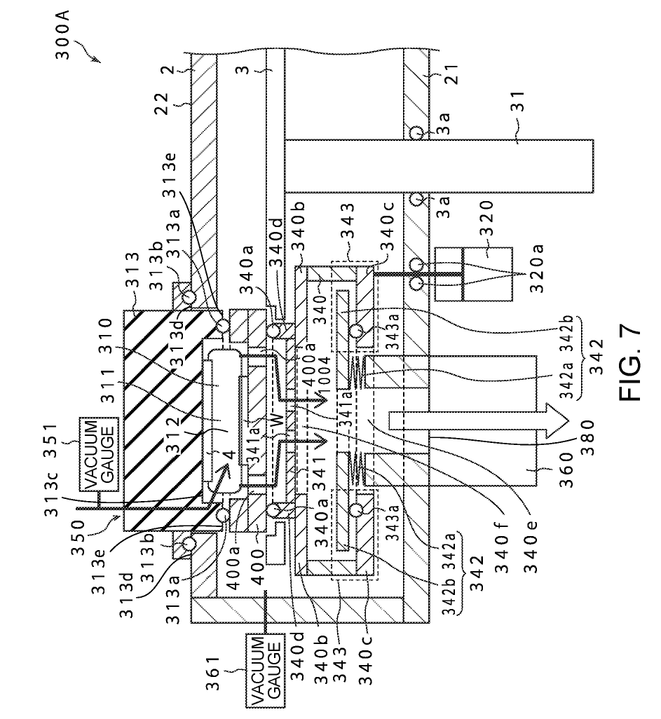

After the process gas G in the film formation room 310 takes the predetermined pressure, the power supplier applies a voltage to the target 4. Then, ions generated from plasma which the process gas G is made into collide with the target 4. The ions strike the film formation material constituting the target 4, and plasma processing of deposition on the film formation target surface WS of the workpiece W is performed (see FIG. 7 and step S4 in FIG. 11).

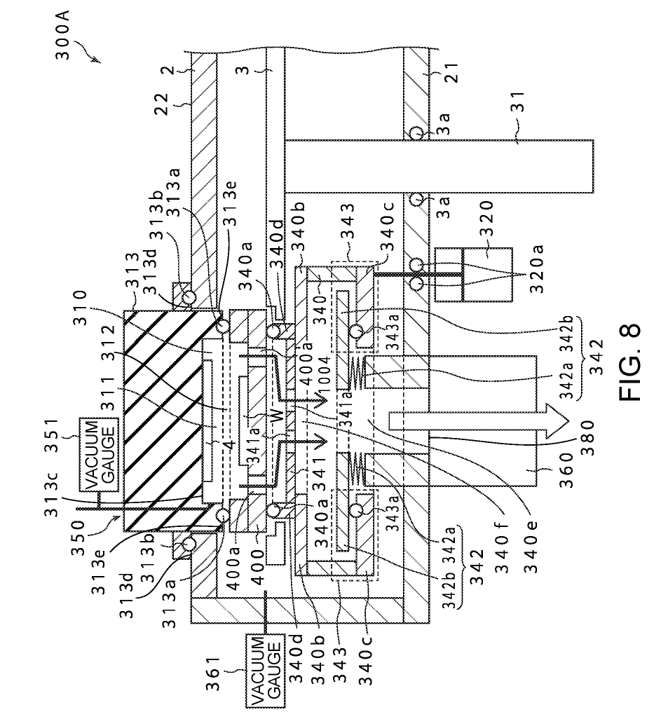

After a required thickness of the film formation material is deposited on the film formation target surface WS of the workpiece W, the power supplier stops applying the voltage to the target 4, and the plasma disappears. After that, the process gas introducer 350 stops feeding the process gas G (step S5). Since, in the film formation room 310 after the plasma processing, the process gas G remains at a higher pressure than the pressure in the chamber 2, when the workpiece holder 400 is lowered in this state, the process gas G results in diffusing into the chamber 2. In order to prevent this, the evacuator 360 keeps the vacuum evacuation of the inside of the film formation room 310 with the exclusive evacuation line (see FIG. 8 and step S6 in FIG. 11).

When the vacuum evacuation of the inside of the film formation room 310 is kept as described above, the pressure in the film formation room 310 is to be lower than the pressure in the chamber 2, which disables the sealing state to be relieved, and the workpiece holder 400 is difficult to be lowered. Therefore, using the vacuum gauge 351 and the vacuum gauge 361, the controller 70 observes the pressure in the film formation room 310 and the pressure in the chamber 2, and when the pressure in the film formation room 310 and the pressure in the chamber 2 take a predetermined pressure difference, the workpiece holder 400 is lowered by the cylinder 320. The predetermined pressure difference can be determined in advance with tests or the like. This pressure difference is a pressure difference at which the cylindrical part 340 can be separated from the workpiece holder 400 by the cylinder 320. Moreover, this is preferable at the time when the predetermined pressure difference is zero, in other words, when the pressure in the film formation room 310 and the pressure in the chamber 2 have the same pressure. Since the process gas G remaining in the film formation room 310 is almost discharged and has the same pressure as that in the chamber 2, the process gas G can be restrained from diffusing into the chamber 2 even after the sealing of the film formation room 310 is relieved. Note that since, even after the sealing of the film formation room 310 is relieved, the evacuation is continued through the through holes 400a of the workpiece holder 400 right below it, the process gas G can be restrained from diffusing into the chamber 2 even though the pressure difference is not zero.

For example, when the pressure difference between the pressure in the film formation room 310 and the pressure in the chamber 2 becomes zero, the cylinder 320 moves the cylindrical part 340 in the direction of separating from the workpiece holder 400 (step S7). In other words, the cylinder 320 lowers the cylindrical part 340 and the workpiece holder 400. As the evacuation line in this stage, a line passing through the cylindrical part 340 via the gap between the workpiece holder 400 and the cylindrical part 340 and further via the inflow obstructor 341 is formed. In the present embodiment, when the vacuum evacuation of the inside of the film formation room 310 is not performed, evacuation of the entirety in the chamber 2 is performed.

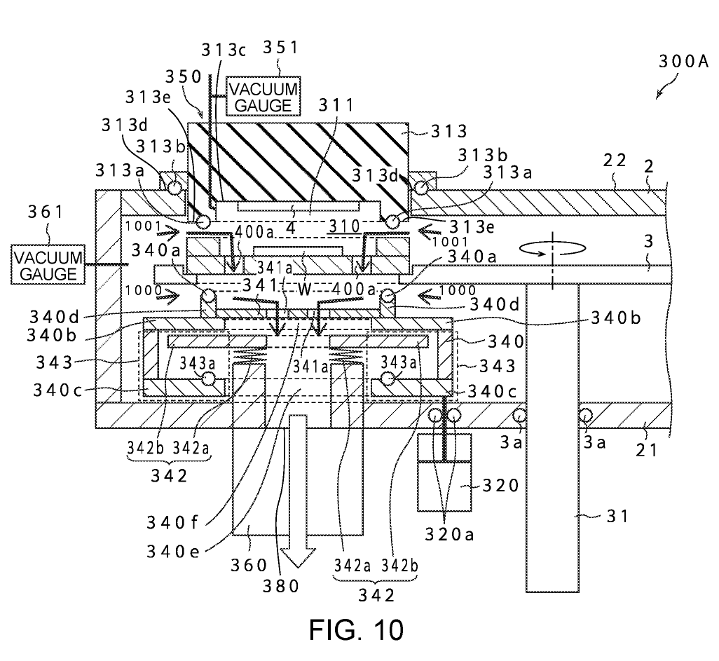

FIG. 10 shows a state where the cylinder 320 has completely lowered the cylindrical part 340. There is formed the evacuation line for the entire chamber 2, and the controller 70 performs vacuum conveyance of the workpiece W having been processed to the film former 300B in the state where the chamber 2 is kept at a predetermined pressure by control of the evacuator 360 (step S8).

Moreover, after, in the film former 300B, the similar processing to that in the film former 300A is performed, the workpiece W undergoes vacuum conveyance to the load lock 120. The workpiece W is taken out from the film formation apparatus 1 via the load lock 120 by a not-shown conveyance mechanism.

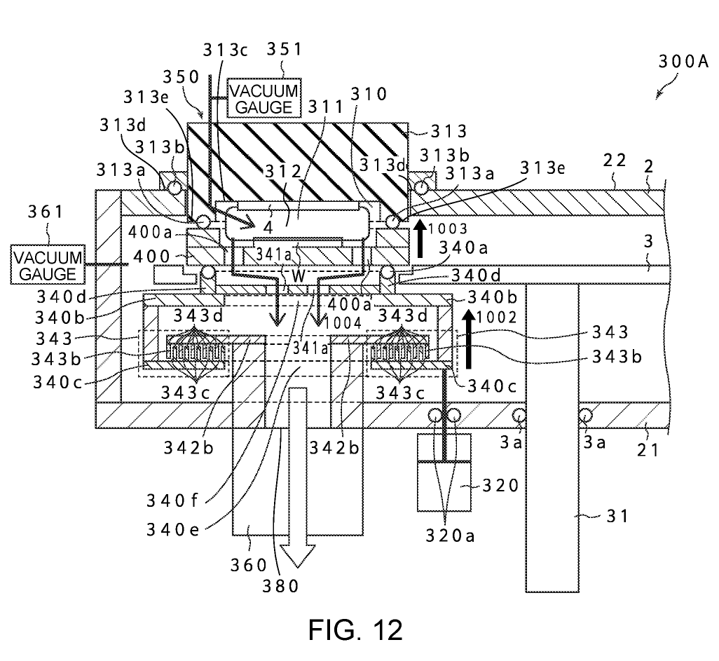

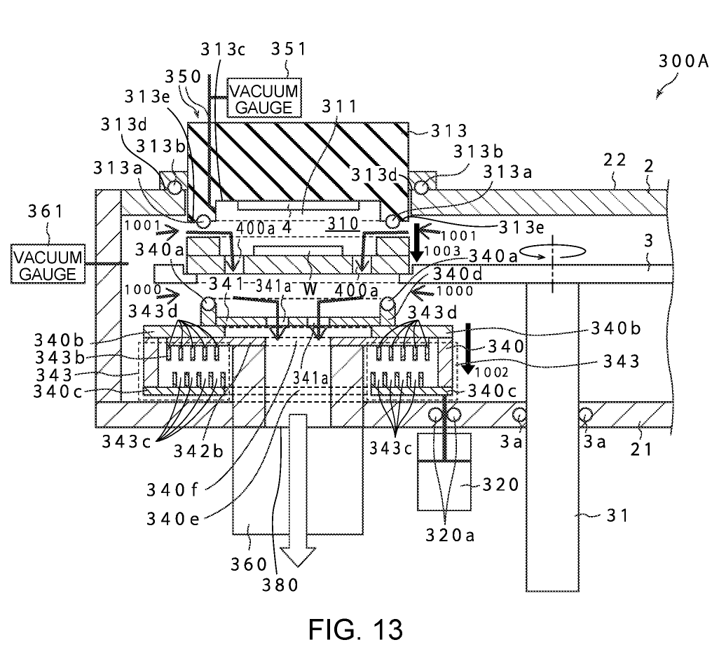

A first modification of the present embodiment is described using FIGS. 12 and 13.

As with FIG. 2, in the present modification, the film former 300A is shown as cross sectional views taken along line A-A. In the present modification, the film former 300A does not include the bellows 342a. Moreover, the film former 300A has a plurality of recess and projection structures 343b on respective surfaces, of the outward flange 342b and the inward flange 340c, which surfaces overlap with each other, in place of including the O-ring of the sealing material 343a in the trap structure 343. Moreover, there is employed a structure in which, by the cylindrical part 340 moving in the +Z-direction to elevate the inward flange 340c, recess parts 343c included on the outward flange 342b are fitted onto projection parts 343d included on the inward flange 340c (in which structure projection parts 343d included on the outward flange 342b are fitted into recess parts 343c included on the inward flange 340c, likewise). Gaps between the recess parts 343c and the projection parts 343d are very small, and a position at which the cylindrical part 340 is elevated and stops is a position at which the recess parts 343c and the projection parts 343d are fitted to each other. The gaps between the recess parts 343c and the projection parts 343d in this state become very small. In this state, the exclusive evacuation line for the film formation room 310 and the space of the chamber 2 scarcely communicate with each other. Namely, when the exclusive evacuation line for the film formation room 310 is formed, the trap structure 343 prevents suction and/or evacuation through the gaps between the outward flange 342b and the inward flange 340c. The film former 300A may include the bellows 342a as with the aforementioned embodiment, in addition to including the plurality of recess and projection structures 343b on the respective surfaces, of the outward flange 342b and the inward flange 340c, which surfaces overlap with each other.

FIG. 13 shows a state where the cylinder 320 lowers the cylindrical part 340. In this stage, a gap arises between the cylindrical part 340 and the workpiece holder 400. When the evacuator 360 operates, as indicated by the directions of the arrows 1000 and the arrows 1001, a line passing from the chamber 2 through the evacuator 360 via this gap is formed as the evacuation line for the entire chamber 2.

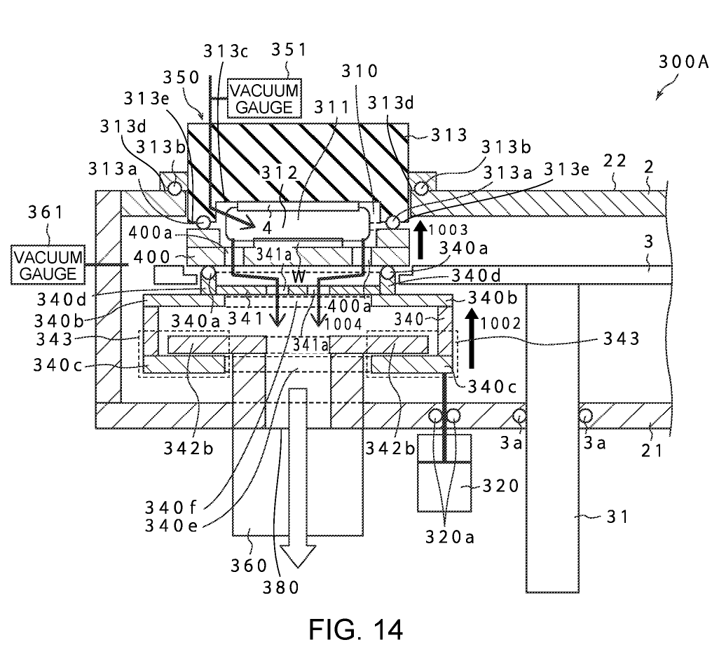

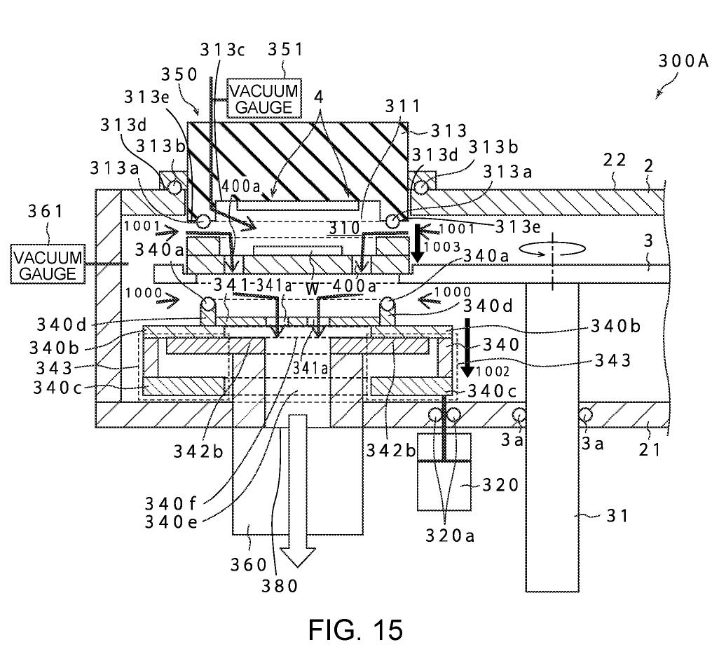

A second modification of the present embodiment is described using FIGS. 14 and 15.

As with FIG. 2, in the present modification, the film former 300A is shown as cross sectional views taken along line A-A. In the present modification, the film former 300A does not include the bellows 342a, and moreover, does not include the O-ring of the sealing material 343a in the trap structure 343. The film former 300A does not necessarily include the bellows 342a or the O-ring in the trap structure 343, and also in such a case, the exclusive evacuation line can be formed (see FIG. 14).

FIG. 15 shows a state where the cylinder 320 lowers the cylindrical part 340. In this stage, a gap arises between the cylindrical part 340 and the workpiece holder 400. When the evacuator 360 operates, as indicated by the directions of the arrows 1000 and the arrows 1001, a line passing from the chamber 2 through the evacuator 360 via this gap is formed as the evacuation line for the entire chamber 2.

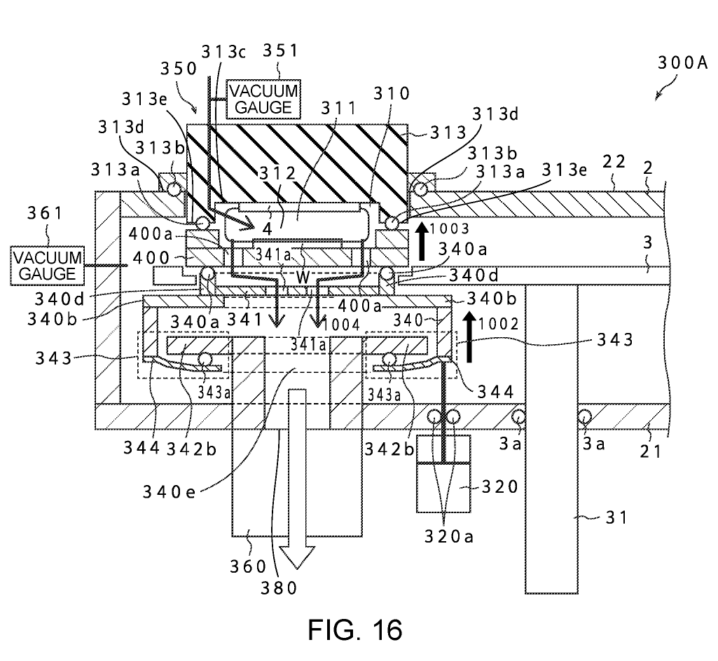

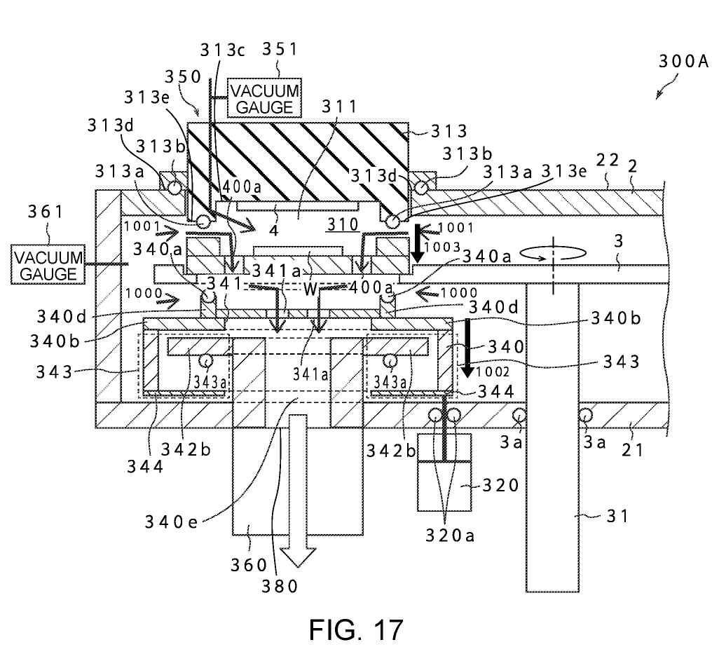

A third modification of the present embodiment is described using FIGS. 16 and 17.

As with FIG. 2, in the present modification, the film former 300A is shown as cross sectional views taken along line A-A. In the present modification, the film former 300A does not include the bellows 342a. Instead, the film former 300A includes a spring plate 344 in the trap structure 343. More specifically, the inward flange 340c of the cylindrical part 340 has a spring plate 344 structure, and when the cylindrical part 340 moves in the +Z-direction, the spring plate 344 comes into contact with the sealing material 343a provided on the outward flange 342b. As above, the trap structure 343 prevents suction and/or evacuation through the gap between the outward flange 342b and the cylindrical part 340. The film former 300A may include the bellows 342a as with the aforementioned embodiment, in addition to including the spring plate 344. No sealing material 343a may be included.

As shown in FIG. 17, the cylinder 320 lowers the cylindrical part 340. In this stage, when the evacuator 360 for which the gap arise between the cylindrical part 340 and the workpiece holder 400 operates, as indicated by the directions of the arrows 1000 and the arrows 1001, a line passing from the chamber 2 through the evacuator 360 via this gap is formed as the evacuation line for the entire chamber 2.

According to the present embodiment and the present modifications, as to the film formation apparatus 1, the evacuators 360 are provided respectively right below the film formers 300A and 300B, the cylindrical part 340 is elevated in film formation processing to be pressed onto the workpiece holder 400, which causes the edge part of the workpiece holder 400 to come into contact with the lid body 313 to form the processing space 312 between the workpiece holder 400 and the lid body 313 and causes the cylindrical part 340 and the workpiece holder 400 to come into contact with each other, and this forms the exclusive evacuation line that discharges the process gas G from the film formation room 310, with the space between the cylindrical part 340 and the workpiece holder 400 and the trap structure 343 in the cylindrical part 340. Thereby, the film formation apparatus 1 can prevent discharge of the process gas G to the chamber 2, and restrain contamination of the inside of the chamber 2.

Moreover, according to the present embodiment and the present modifications, the film formation apparatus 1 uses the evacuators 360 for evacuation of the entire chamber 2 except in the case of film formation processing. There is provided the evacuator 370 that evacuates the space in the chamber 2, when the film formation processing is not performed, the cylindrical part 340 is positioned at a lowered position to cause the cylindrical part 340, the workpiece holder 400, and the lid body 313 to separate from one another and to communicate with the space of the chamber 2, and thereby the evacuation lines for the evacuators 360 communicate with the space of the chamber 2. Thereby, each evacuator 360 can evacuate the space in the chamber 2. In other words, since elevating and lowering operation of the cylindrical part 340 can switch the evacuation by the evacuator 360 between evacuation of the inside of the film formation room 310 and evacuation of the entire inside of the chamber 2, an exclusive evacuator for the chamber 2 does not need to be provided. Thereby, a separate evacuator other than those for the film formers does not need to be provided in the chamber 2, and a cost and a space can be reduced. On the other hand, if there is employed a sealing structure that uses gate valves for each film formation room 310, this results in complex structures, complex processes, and deterioration in tact time. Note that, without limitation to this, an exclusive evacuator 370 for the chamber 2 may be provided. This enables the inside of the chamber 2 to be quickly evacuated together with the evacuators 360. For example, as to reducing the pressure in the chamber 2 to a predetermined pressure value before the workpieces W are carried into the chamber 2 from the load lock 120, while only the evacuator 370 conventionally performs the evacuation, the evacuators 360 can be added according to the present embodiment, which can reduce a time for reducing the pressure in the chamber 2 to the predetermined pressure. This contributes to reduction in tact time.

Moreover, according to the present embodiment and the present modifications, as to the film formation apparatus 1, since the evacuators 360 are provided respectively right below the film formers 300A and 300B, spaces where the evacuators 360 are installed can be more easily secured than in the case where the film formation rooms 310 and 310 are evacuated sideways.

Moreover, according to the present embodiment and the present modifications, as to the film formation apparatus 1, the through holes 341a and the through holes 400a are not provided on identical lines, and moreover, a space is provided between the inflow obstructor 341 and the workpiece holder 400. Thereby, in sputtering, even when the film formation room 310 becomes full of the process gas G, there can be prevented sputter particles from flowing into the through holes 400a and/or 341a to be deposited as a film and the through holes from being closed.

Moreover, according to the present embodiment, as to the film formation apparatus 1, the bellows mechanism 342 which includes the trap structure 343 including the cylindrical part 340 and the evacuator 360 forms the exclusive evacuation line. Supposing that the bellows mechanism 342 were not provided, when the cylindrical part 340 is elevated in the state of being inclined, elevating the cylindrical part 340 would be stopped in the state where a part of the sealing material 343a is in contact with the outward flange 342b. This causes a displacement in parallel, which disables a sealing mechanism to be attained. Here, in parallel means the state of parallelism at which, when the cylindrical part 340 is elevated by the cylinder, the sealing material 343a on the inward flange 340c of the cylindrical part 340 comes into contact with the outward flange 342b. Therefore, by employing the bellows mechanism 342 on the outward flange 342b, the parallelism of the outward flange 342b can be flexible to some extent. In other words, even when the cylindrical part 340 is elevated while being inclined, when a part of the sealing material 343a first comes into contact with the outward flange 342b, the bellows mechanism 342 enables the outward flange 342b to follow the inclination of the inward flange 340c of the cylindrical part 340 at this time point, and the sealing material 343a can completely come into contact with the outward flange 342b. Thereby, the displacement in parallel in the film formation apparatus 1 can be offset.

While some embodiments have been described as above, these embodiments are presented for examples only and are not intended to limit the claims. This novel film formation apparatus 1 described in the present specification can be implemented for the preprocessing device 200, a film processing device that nitrides or oxidizes the film formed on the workpiece W, and the similar devices in various another modes. Moreover, various omissions, replacements, combinations, and alterations of the modes of the film formation apparatus 1 described in the present specification may occur without departing from the spirit of the invention. The appended claims and their equivalents are intended to include those modes and their modifications included in the scope and the spirit of the invention.

1. A film formation apparatus comprising:
a chamber configured such that an inside of the chamber is able to be evacuated to a vacuum;
a lid body provided to face an interior of the chamber via an opening of an upper part of the chamber;
a target provided on the lid body and formed to include a film formation material that is to be deposited on a workpiece as a processed object by sputtering;
a film formation room in which a film is formed on the workpiece arranged on a workpiece holder through sputtering of the target with plasma, the film formation room being formed in the chamber by the lid body and the workpiece holder that includes a first through hole;
a conveyance body configured to rotate intermittently and to position the workpiece holder at a position corresponding to the lid body, the workpiece holder being placed on the conveyance body;
a cylindrical part configured to move the workpiece holder to a position in contact with the lid body from the conveyance body;
an inward flange formed at a lower end of the cylindrical part and extending in an inward direction from the lower end;
an outward flange configured to come adjacent to and overlap with the inward flange while the cylindrical part moves and to obstruct entry of evacuated gas into the chamber, the outward flange being provided inside the cylindrical part and extending in an outward direction in the cylindrical part;
a lift mechanism configured to elevate and lower the cylindrical part such that the cylindrical part comes into contact with and separates from the workpiece holder; and
an evacuator configured to perform vacuum evacuation, the evacuator being provided at an opening in a bottom part of the chamber to face the film formation room, wherein
the lift mechanism
elevates the cylindrical part to bring the workpiece holder into contact with a lower edge of the lid body,
causes the outward flange to come adjacent to and overlap with the inward flange, and
causes the inside of the cylindrical part to communicate with the evacuator to form a first evacuation line that performs vacuum evacuation of a processing space of the film formation room, via the first through hole from the film formation room.

2. The film formation apparatus according to claim 1, wherein
the lift mechanism
lowers the cylindrical part, and
forms a second evacuation line that passes from the chamber through the inside of the cylindrical part via a gap formed between the workpiece holder and the cylindrical part.

3. The film formation apparatus according to claim 1, wherein the cylindrical part includes an inflow obstructor configured to obstruct inflow of sputter particles generated in the film formation room into the cylindrical part, the inflow obstructor including a second through hole and being arranged on an upper part of the cylindrical part.

4. The film formation apparatus according to claim 3, wherein the second through hole is provided so as not to be on a same line as the first through hole.

5. The film formation apparatus according to claim 3, wherein a space is provided between the inflow obstructor and the workpiece holder when the cylindrical part comes into contact with the workpiece holder.

6. The film formation apparatus according to claim 1, further comprising
bellows configured to support the outward flange, the bellows extending from an opening in the bottom part of the chamber toward the cylindrical part, wherein
the bellows expands and contracts with motion of the cylindrical part.

7. The film formation apparatus according to claim 1, wherein a sealing material is included in at least one of: between the inward flange and the outward flange; between the workpiece holder and the cylindrical part; and between the film formation room and the workpiece holder.

8. The film formation apparatus according to claim 1, wherein each of the inward flange and the outward flange has a recess and projection structure.

9. The film formation apparatus according to claim 1, wherein the inward flange is constituted of a spring plate.

10. The film formation apparatus according to claim 1, wherein the lift mechanism moves the cylindrical part in a direction of separating from the workpiece holder when a pressure difference between a pressure value in the film formation room and a pressure value in the chamber becomes a set value.

11. A film formation method comprising:
positioning a workpiece holder including one or a plurality of first through holes at a position corresponding to a lid body provided in an opening in an upper part of a chamber configured such that an inside of the chamber is able to be evacuated to a vacuum, a workpiece as a processed object being placed on the workpiece holder;
moving, by a cylindrical part, the workpiece holder to a position in contact with the lid body to form a film formation room, and forming a first evacuation line that performs vacuum evacuation of the film formation room, via the first through hole of the workpiece holder;
performing vacuum evacuation of a processing space of the film formation room via the first evacuation line; and
forming a film on the workpiece placed on the workpiece holder through sputtering of a target with plasma.

12. The film formation method according to claim 11, wherein
the forming the first evacuation line includes
causing an outward flange extending in an outward direction inside the cylindrical part to come adjacent to and overlap with an inward flange extending in an inward direction of the cylindrical part while the cylindrical part moves.
